(19) United States
(12) Patent Application Publication
(10) Pub. No.: US 2026/0231654 A1
(43) Pub. Date: Aug. 6, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: WOOYOUNG KIM, YONGIN-SI (KR); KYEONGJONG KIM, YONGIN-SI (KR); SU JEONG KIM, YONGIN-SI (KR); ISRAEL ESTEBAN LAZO MARTINEZ, YONGIN-SI (KR); JUNG-WOO LEE, YONGIN-SI (KR); JINHYEONG LEE, YONGIN-SI (KR)

(21) Appl. No.: 19/320,007

(22) Filed: Sep. 5, 2025

(30) Foreign Application Priority Data
Feb. 5, 2025 (KR) 10-2025-0014374

(51) Int. Cl. H10K 59/80

(52) U.S. Cl. CPC H10K 59/879; H10K 59/8792

(57) ABSTRACT

A display device includes a substrate including light-emitting areas and a non-light-emitting area surrounding the light-emitting areas, light-emitting elements disposed in the light-emitting areas on the substrate, respectively, a reflective pattern disposed on the light-emitting elements which reflects light emitted from the light-emitting elements to the exterior, a light-absorbing pattern disposed on the reflective pattern which absorbs external light, a color filter layer disposed on the light-absorbing pattern and overlapping the light-absorbing pattern in a plan view, and a lens structure disposed on the color filter layer and which redirects a path of the external light to the light-absorbing pattern.

### CROSS-REFERENCE TO RELATED APPLICATION(S)

This application claims priority to and the benefit of Korean Patent Application No. 10-2025-0014374 filed on Feb. 5, 2025 in the Korean Intellectual Property Office, the entire disclosure of which is incorporated by reference herein.

### TECHNICAL FIELD

This disclosure relates generally to a display device and an electronic device including the same. More particularly, this disclosure relates to reducing external light reflection in a display device.

### DISCUSSION OF RELATED ART

External light incident on a display device may be reflected by the lines, electrodes, or the like of the display device. To prevent reflection by the external light, a display device generally includes a polarizing plate. However, the light emitting efficiency of the display device may be reduced due to the polarizing plate.

### SUMMARY

Embodiments provide a display device with improved display quality.

Embodiments provide an electronic device including the display device.

In an embodiment, a display device includes a substrate including light-emitting areas and non-light-emitting area surrounding the light-emitting areas; and light-emitting elements disposed in the light-emitting areas on the substrate, respectively. The display device further includes a reflective pattern (e.g., a pattern of conductive structures) disposed on the light-emitting elements which reflects light emitted from the light-emitting elements to the exterior. A light-absorbing pattern is disposed on the reflective pattern and absorbs external light. A color filter layer is disposed on the light-absorbing pattern and overlaps the light-absorbing pattern in a plan view. A lens structure is disposed on the color filter layer and redirects a path of the external light to the light-absorbing pattern.

In an embodiment, the lens structure may include a first lens disposed on the color filter layer and overlapping the reflective pattern and the light-absorbing pattern, and a second lens entirely surrounding the first lens in a plan view and having a refractive index greater than a refractive index of the first lens.

In an embodiment, the refractive index of the first lens may be in a range of about 1.6 or more and less than about 1.7, and the refractive index of the second lens may be in a range of about 1.7 or more and less than about 2.5.

In an embodiment, a thickness of a center of the first lens may be in a range of about 1.8 um to about 2.0 um, and a thickness of a center of the second lens may be in a range of about 0.9 um to about 1.0 um.

In an embodiment, each of the light-absorbing pattern and the lens structure may have a circular shape or a rectangular shape in a plan view.

In an embodiment, the light-emitting areas may include first, second and third light-emitting areas which emit light of different colors. The color filter layer may include first, second and third color filters overlapping the first, second and third light-emitting areas, respectively in a plan view. The lens structure may include first, second, and third lens structures overlapping the first, second and third light-emitting areas, respectively in a plan view. The first lens structure may have a first length in a direction parallel to a surface of the substrate. The second lens structure may have a second length in the direction. The third lens structure may have a third length in the direction which is shorter than each of the first length and the second length.

In an embodiment, the light-absorbing pattern may include first, second and third light-absorbing patterns overlapping the first, second and third light-emitting areas, respectively in a plan view. In a plan view, a first shortest distance from an edge portion of the first light-absorbing pattern to an edge portion of the first lens structure or a second shortest distance from an edge portion of the second light-absorbing pattern to an edge portion of the second lens structure may be twice a third shortest distance from an edge portion of the third light-absorbing pattern to an edge portion of the third lens structure in a plan view.

In an embodiment, the third shortest distance may be in a range of about 1 um to about 2 um.

In an embodiment, the first color filter may be a red color filter, the second color filter may be a green color filter, and the third color filter may be a blue color filter.

In an embodiment, the display device may further include a black matrix disposed in the non-light-emitting area and on the reflective pattern. The light-absorbing pattern and the black matrix may include a same material.

In an embodiment, the display device may further include a first touch electrode disposed on the non-light-emitting area, a second touch electrode disposed on the first touch electrode and connected to the first touch electrode, and an overcoat layer overlapping the color filter layer and the lens structure.

In an embodiment, the reflective pattern and the second touch electrode may include a same material.

In an embodiment, the lens structure may have a cross-sectional shape which is a trapezoid or a trapezoid with rounded sides.

In an embodiment, the lens structure has a convex shape in a cross section.

An electronic device according to embodiments of the disclosure includes a display device and a processor which controls the display device. The display device includes a substrate including light-emitting areas and non-light-emitting area surrounding the light-emitting areas, light-emitting elements disposed in the light-emitting areas on the substrate, respectively. The display device further includes a reflective pattern disposed on the light-emitting elements which reflects light emitted from the light-emitting elements to the exterior, a light-absorbing pattern disposed on the reflective pattern which absorbs external light, a color filter layer disposed on the light-absorbing pattern and overlapping the light-absorbing pattern, and a lens structure disposed on the color filter layer and which redirects a path of the external light to the light-absorbing pattern.

In an embodiment, the lens structure may include a first lens disposed on the color filter layer and overlapping the reflective pattern and the light-absorbing pattern in a plan view, and a second lens entirely surrounding the first lens and having a refractive index greater than a refractive index of the first lens.

In an embodiment, the refractive index of the first lens may be in a range of about 1.6 or more and less than about 1.7, and the refractive index of the second lens may be in a range of about 1.7 or more and less than about 2.5.

In an embodiment, a thickness of a center of the first lens may be in a range of about 1.8 um to about 2.0 um, and a thickness of a center of the second lens may be in a range of about 0.9 um to about 1.0 um.

In an embodiment, the light-emitting areas may include first, second and third light-emitting areas which emit light of different colors. The color filter layer may include first, second and third color filters overlapping the first, second and third light-emitting areas, respectively in a plan view. The lens structure may include first, second, and third lens structures overlapping the first, second and third light-emitting areas, respectively in a plan view. The first lens structure may have a first length in a direction parallel to a surface of the substrate. The second lens structure may have a second length in the direction. The third lens structure may have a third length in the direction which is shorter than each of the first length and the second length.

In an embodiment, the light-absorbing pattern may include first, second and third light-absorbing patterns overlapping the first, second and third light-emitting areas, respectively in a plan view. A first shortest distance from an edge portion of the first light-absorbing pattern to an edge portion of the first lens structure or a second shortest distance from an edge portion of the second light-absorbing pattern to an edge portion of the second lens structure may be twice a third shortest distance from an edge portion of the third light-absorbing pattern to an edge portion of the third lens structure in a plan view, and the third shortest distance may be in a range of about 1 um to about 2 um.

The display device according to embodiments of the disclosure might not include a separate polarizing plate by including a black matrix and a color filter layer. Accordingly, weight and thickness of the display device may be reduced, and visibility of the display device may be improved.

The display device may include a light-absorbing pattern disposed in a display area and overlapped by a color filter layer in a plan view. The light-absorbing pattern and the black matrix may include a same material. Accordingly, the light-absorbing pattern may absorb external light. As a result, external light reflectance of the display device may be reduced, reflection color may be improved, and thus display quality of the display device may be improved.

The display device may further include a reflective pattern overlapping the light-absorbing pattern. Accordingly, a portion of light emitted from a light-emitting element may be reflected by the reflective pattern, and a portion of light reflected by the reflective pattern may be reflected again by structures (e.g., a common electrode, or the like) under the reflective pattern and emitted to the exterior of the display device. Accordingly, recycling efficiency of the light emitted from the light-emitting element may be improved, so that display quality of the display device may be improved.

The display device may further include a lens structure disposed on the color filter layer and overlapping the reflective pattern and the light-absorbing pattern in a plan view. Accordingly, the external light might not be reflected, and path of the external light may be refracted into the light-absorbing pattern by the lens structure. As a result, the external light may be absorbed by the light-absorbing pattern, and external light reflectance of the display device may be reduced, so that the display quality of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment.

FIG. 2 is an enlarged plan view of area A of FIG. 1 according to an embodiment.

FIG. 3 is an example cross-sectional view taken along line I-I′ of FIG. 2.

FIG. 4 is an enlarged example cross-sectional view of area B1 of FIG. 3.

FIG. 5 is an enlarged example cross-sectional view of area B2 of FIG. 3.

FIG. 6 is an enlarged example cross-sectional view of area B3 of FIG. 3.

FIGS. 7 to 15 are respective example cross-sectional views illustrating a method for manufacturing a display device according to an embodiment.

FIG. 16 is an example plan view of area A of FIG. 1 according to an embodiment.

FIG. 17 is an example cross-sectional view taken along line I-I′ of FIG. 2.

FIG. 18 is a block diagram of an electronic device according to an embodiment of the disclosure.

FIG. 19 depicts example electronic devices according to various respective embodiments.

### DETAILED DESCRIPTION

Hereinafter, embodiments of the disclosure will be described in more detail with reference to the accompanying drawings. In the drawings, the same reference numerals/characters are used for the same components in the drawings, and redundant descriptions of the same components will not be provided for conciseness.

While each drawing may represent one or more particular embodiments of the present disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the disclosure, for example, to allow for manufacturing limitations and the like.

In this specification, a plane may be defined by a first direction DR1 and a second direction DR2 that intersects the first direction DR1. For example, the second direction DR2 may be perpendicular to the first direction DR1.

Herein, the term “pattern”, in the context of a circuit element or elements, may refer to a structure of the circuit element (such as a conductive line or patch) or to an arrangement of a plurality of circuit elements.

Embodiments of the disclosure provide a design for a display device having improved suppression of external light, improved light emission efficiency, and that compensates distortion or decreases luminance of blue light. For example, a light absorbing pattern, a reflective pattern, and a two-layered lens structure are included to overlap each light emitting element in a plan view. The light absorbing pattern is included to absorb external light. Furthermore, the two layers of the lens structure have differing refractive indices to further suppress the reflection of external light by concentrating external light at the light absorbing pattern. The reflective pattern is included to reflect light produced by the light emitting element so that it can again be reflected by an underlying electrode to the exterior so that light emitting efficiency is not reduced. Lastly, the relative size of the two-layered lens structure as compared to the light absorbing pattern corresponding to the blue sub-pixels is designed differently than other colored sub-pixels to compensate for distortion or brightness of the blue light.

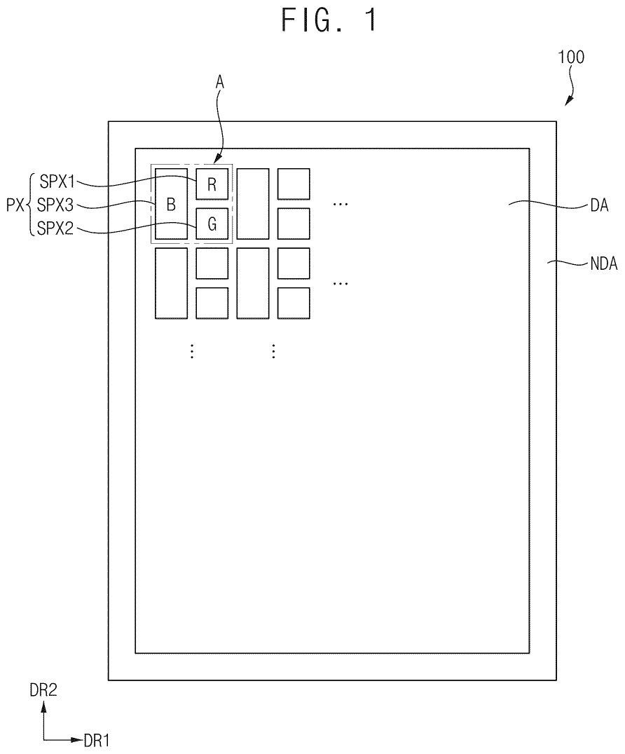

FIG. 1 is a schematic plan view illustrating a display device according to an embodiment.

Referring to FIG. 1, a display device 100 according to an embodiment of disclosure may include a display area DA and a non-display area NDA. The display area DA may mean an area which displays an image. The non-display area NDA may be disposed around the display area DA. For example, the non-display area NDA may entirely surround the display area DA.

The display device 100 may include multiple pixels PX disposed in the display area DA. In a plan view, the pixels PX may be repeatedly arranged (or ‘disposed’) along the first direction DR1 and the second direction DR2.

Each of the pixels PX may include multiple sub-pixels which emit light of different colors. In an embodiment, each of the pixels PX may include first, second, and third sub-pixels SPX1, SPX2, and SPX3 which may emit light of different colors. For example, the first sub-pixel SPX1 may emit red light, the second sub-pixel SPX2 may emit green light, and the third sub-pixel SPX3 may emit blue light, but the disclosure is not necessarily limited thereto. For example, the first, second, and third sub-pixels SPX1, SPX2, and SPX3 may be combined so that each of the pixels PX emits yellow, cyan, and magenta lights.

In an embodiment, the arrangement structure of the first, second, and third sub-pixels SPX1, SPX2, and SPX3 may be an S-stripe structure. For example, the third sub-pixel SPX3 may be arranged (or ‘disposed’) in a first column, and the first and second sub-pixels SPX1 and SPX2 may be arranged (or ‘disposed’) in sequence in a second column adjacent to the first column. The third sub-pixel SPX3 may have a rectangular planar shape in a plan view having a long side in the second direction DR2, and each of the first and second sub-pixels SPX1 and SPX2 may have a rectangular planar shape. Herein, “a plan view” of a structure refers to a view from a remote point from a major surface of the structure. In other words, a side extending in the second direction DR2 of each of the first and second sub-pixels SPX1 and SPX2 may be arranged to face the long side of the third sub-pixel SPX3. However, the disclosure is not necessarily limited thereto. For example, the arrangement structure of the first, second, and third sub-pixels SPX1, SPX2, and SPX3 may have a PenTile™ structure.

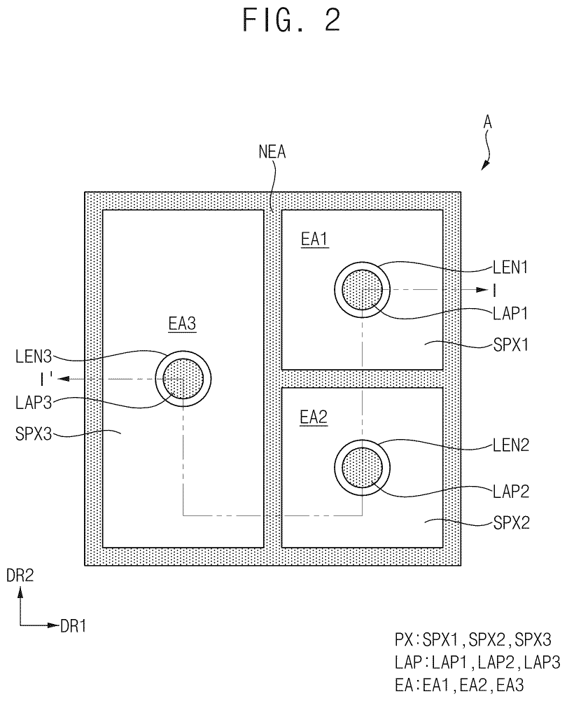

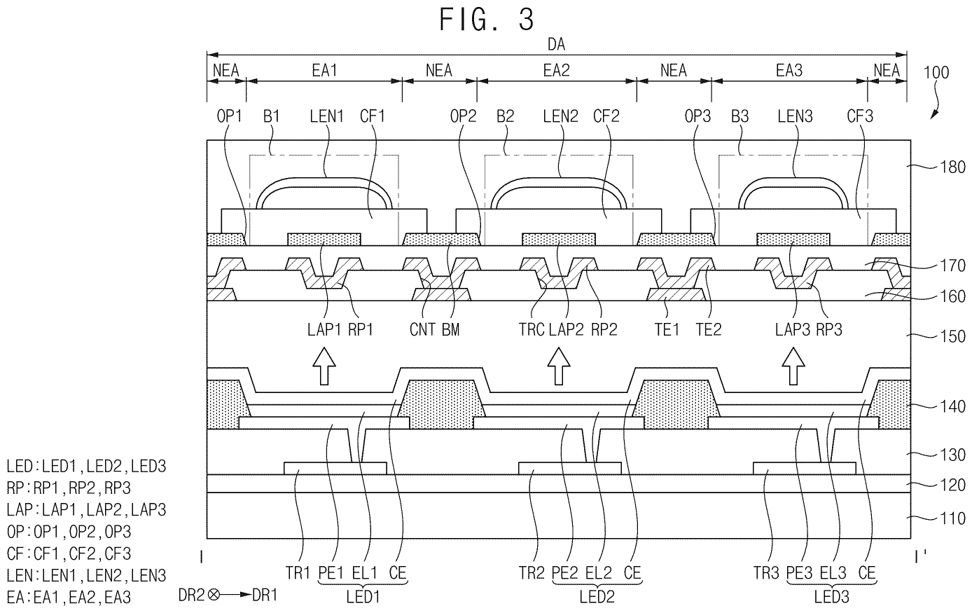

FIG. 2 is a plan view of an embodiment, which is an enlarged view of area A of FIG. 1. FIG. 3 is a schematic cross-sectional view of an embodiment taken along line I-I′ of FIG. 2.

Referring to FIGS. 2 and 3, the display area DA may include light-emitting areas EA and a non-light-emitting area NEA. The light-emitting areas EA may include a first light-emitting area EA1, a second light-emitting area EA2, and a third light-emitting area EA3. Each of the first, second, and third light-emitting areas EA1, EA2, and EA3 may be an area in which light emitted from a light-emitting element LED (see FIG. 3) is emitted to the exterior of the display device 100. For example, the first light-emitting area EA1 may emit first transmitted light, the second light-emitting area EA2 may emit second transmitted light, and the third light-emitting area EA3 may emit third transmitted light. In an embodiment, the first transmitted light may be red light, the second transmitted light may be green light, and the third transmitted light may be blue light.

The first sub-pixel SPX1 may overlap the first light-emitting area EA1, the second sub-pixel SPX2 may overlap the second light-emitting area EA2, and the third sub-pixel SPX3 may overlap the third light-emitting area EA3.

The first, second, and third light-emitting areas EA1, EA2, and EA3 may have different sizes. In an embodiment, the third light-emitting area EA3 may be larger than the first and second light-emitting areas EA1 and EA2. However, the disclosure are not necessarily limited thereto, and the sizes of the first, second, and third light-emitting areas EA1, EA2, and EA3 may be determined in various ways as needed.

Each of the first, second, and third light-emitting areas EA1, EA2, and EA3 may have a triangular planar shape, a rectangular planar shape, a circular planar shape, a track-shaped planar shape, an elliptical planar shape, or the like in a plan view. In an embodiment, each of the first, second, and third light-emitting areas EA1, EA2, and EA3 may have a rectangular planar shape in a plan view. However, the disclosure are not necessarily limited thereto.

The non-light-emitting area NEA may surround each of the first, second, and third light-emitting areas EA1, EA2, and EA3 in a plan view. For example, the non-light-emitting area NEA may have a grid shape in a plan view. The non-light-emitting area NEA may be an area which does not emit light.

Referring further to FIG. 3, the display device 100 according to an embodiment of the disclosure may include a substrate 110, a buffer layer 120, first, second, and third transistors TR1, TR2, and TR3, an insulating structure 130, a pixel defining layer 140, a light-emitting elements LED, an encapsulation layer 150, a first touch electrode TE1, a first touch insulating layer 160, a second touch electrode TE2, a reflective pattern RP, a second touch insulating layer 170, a black matrix BM, a light-absorbing pattern LAP, a color filter layer CF, a lens structure LEN, and an overcoat layer 180.

Here, the light-emitting element LED may include a first light-emitting element LED1, a second light-emitting element LED2, and a third light-emitting element LED3. The reflective pattern RP may include a first reflective pattern RP1, a second reflective pattern RP2, and a third reflective pattern RP3. The light-absorbing pattern LAP may include a first light-absorbing pattern LAP1, a second light-absorbing pattern LAP2, and a third light-absorbing pattern LAP3. The color filter layer CF may include a first color filter CF1, a second color filter CF2, and a third color filter CF3. The lens structure LEN may include a first lens structure LEN1, a second lens structure LEN2, and a third lens structure LEN3.

As described above, the display device 100 may include the first, second, and third light-emitting areas EA1, EA2, and EA3 and the non-light-emitting area NEA. As the display device 100 includes the first, second, and third light-emitting areas EA1, EA2, and EA3 and the non-light-emitting area NEA, components (e.g., the substrate 110, or the like) included in the display device 100 may also include the first, second, and third light-emitting areas EA1, EA2, and EA3 and the non-light-emitting area NEA.

The substrate 110 may include a transparent material or an opaque material. In an embodiment, the substrate 110 may be formed of glass, quartz, silicon, plastic, or the like. Examples of plastics which can be used for the substrate 110 may include polyimide (PI), polypropylene (PP), polycarbonate (PC), polystyrene (PS), polyethylene (PE), polyethersulfone (PES), and/or the like. These can be used alone or in combination with each other.

The buffer layer 120 may be disposed on the substrate 110. The buffer layer 120 may prevent impurities such as oxygen and moisture from diffusing to an upper portion of the substrate 110 through the substrate 110, and may planarize an upper surface of the substrate 110. In an embodiment, the buffer layer 120 may include an inorganic insulating material such as a silicon compound, a metal oxide, or the like. Examples of inorganic insulating materials which can be used as the buffer layer BF include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), and/or the like. These can be used alone or in combination with each other. The buffer layer 120 may have a single-layer structure or a multi-layer structure including multiple insulating layers. In an embodiment, the buffer layer 120 may be omitted.

The first, second, and third transistors TR1, TR2, and TR3 may be disposed on the buffer layer 120. Active patterns of the first, second, and third transistor TR1, TR2, and TR3 may include an oxide semiconductor, a silicon semiconductor, or an organic semiconductor. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), and/or the like. These can be used alone or in combination with each other. The silicon semiconductor may include amorphous silicon, polycrystalline silicon, or the like.

The insulating structure 130 may cover the first, second, and third transistors TR1, TR2, and TR3. The insulating structure 130 may include at least one inorganic insulating layer and at least one organic insulating layer. Examples of inorganic insulating materials which can be used as the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), and/or the like. Examples of organic insulating materials which can be used as the organic insulating layer may include photoresist, polyacryl-based resin, polyimide-based resin, polyamide-based resin, siloxane-based resin, acryl-based resin, epoxy-based resin, and/or the like. These can be used alone or in combination with each other.

The first, second, and third pixel electrodes PE1, PE2, and PE3 may be disposed on the insulating structure 130. For example, the first pixel electrode PE1 may overlap the first light-emitting area EA1, the second pixel electrode PE2 may overlap the second light-emitting area EA2, and the third pixel electrode PE3 may overlap the third light-emitting area EA3 in a plan view.

Each of the first, second, and third pixel electrodes PE1, PE2, and PE3 may include a conductive material such as a metal, an alloy, a conductive metal nitride, a conductive metal oxide, a transparent conductive material, and/or the like. Examples of conductive materials which can be used as the first, second, and third pixel electrodes PE1, PE2, and PE3 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), and/or the like. These can be used alone or in combination with each other.

Each of the first, second, and third pixel electrodes PE1, PE2, and PE3 may have a single-layer structure or a multi-layer structure including multiple conductive layers. The first, second, and third pixel electrodes PE1, PE2, and PE3 may be electrically connected to the first, second, and third transistors TR1, TR2, and TR3 through contact holes formed in the insulating structure 130, respectively.

The pixel defining layer 140 may be disposed on the first, second, and third pixel electrodes PE1, PE2, and PE3. The pixel defining layer 140 may overlap the non-light-emitting area NEA. A pixel opening which exposes at least a portion of each of the first, second, and third pixel electrodes PE1, PE2, and PE3 may be defined in the pixel defining layer 140. The light-emitting areas EA and the non-light-emitting area NEA of the display device 100 may be defined by the pixel opening. For example, an area where the pixel opening is disposed may correspond to the light-emitting areas EA, and an area where the pixel defining layer 140 is disposed may correspond to the non-light-emitting area NEA. For example, the pixel defining layer 140 may include an inorganic insulating material or an organic insulating material. Optionally, the pixel defining layer 140 may further include a light-blocking material having a black color.

The first, second, and third light-emitting layers EL1, EL2, and EL3 may be disposed on the first, second, and third pixel electrodes PE1, PE2, and PE3 exposed by the pixel opening of the pixel defining layer 140, respectively. For example, the first light-emitting layer EL1 may be disposed on the first pixel electrode PE1, the second light-emitting layer EL2 may be disposed on the second pixel electrode PE2, and the third light-emitting layer EL3 may be disposed on the third pixel electrode PE3. For example, the first light-emitting layer EL1 may overlap the first light-emitting area EA1, the second light-emitting layer EL2 may overlap the second light-emitting area EA2, and the third light-emitting layer EL3 may overlap the third light-emitting area EA3.

For example, the first light-emitting layer EL1 may include a light-emitting material which emits red light, the second light-emitting layer EL2 may include a light-emitting material which emits green light, and the third light-emitting layer EL3 may include a light-emitting material which emits blue light.

A common electrode CE may be disposed on the first, second, and third light-emitting layers EL1, EL2, and EL3. For example, the common electrode CE may include a conductive material such as a metal, an alloy, a conductive metal nitride, a conductive metal oxide, a transparent conductive material, and/or the like. The common electrode CE may have a single-layer structure or a multi-layer structure including multiple conductive layers. In an embodiment, the common electrode CE may extend continuously across the light-emitting areas EA and the non-light-emitting area NEA.

Accordingly, the first pixel electrode PE1, the first light-emitting layer EL1, and the common electrode CE may form the first light-emitting element LED1, the second pixel electrode PE2, the second light-emitting layer EL2, and the common electrode CE may form the second light-emitting element LED2, and the third pixel electrode PE3, the third light-emitting layer EL3, and the common electrode CE may form the third light-emitting element LED3. For example, the first light-emitting element LED1 may emit red light, the second light-emitting element LED2 may emit green light, and the third light-emitting element LED3 may emit blue light. Accordingly, a red sub-pixel including the first transistor TR1 and the first light-emitting element LED1, a green sub-pixel including the second transistor TR2 and the second light-emitting element LED2, and a blue sub-pixel including the third transistor TR3 and the third light-emitting element LED3 may be formed.

The encapsulation layer 150 may be disposed on the common electrode CE. The encapsulation layer 150 may include at least one inorganic encapsulation layer and at least one organic encapsulation layer. For example, the encapsulation layer 150 may include a first inorganic encapsulation layer disposed on the common electrode CE, an organic encapsulation layer disposed on the first inorganic encapsulation layer, and a second inorganic encapsulation layer disposed on the organic encapsulation layer.

The first touch electrode TE1 may be disposed on the encapsulation layer 150. In an embodiment, the first touch electrode TE1 may overlap the non-light-emitting area NEA. For example, the first touch electrode TE1 may include a conductive material.

The first touch insulating layer 160 may be disposed on the encapsulation layer 150. The first touch insulating layer 160 may cover the first touch electrode TE1. The first touch insulating layer 160 may sufficiently cover the first touch electrode TE1. Accordingly, the first touch insulating layer 160 may have a substantially flat upper surface without generating a step around the first touch electrode TE1. For example, the first touch insulating layer 160 may include an organic insulating material or an inorganic insulating material.

The second touch electrode TE2 may be disposed on the first touch insulating layer 160. In an embodiment, the second touch electrode TE2 may overlap the non-light-emitting area NEA in a plan view. The second touch electrode TE2 may be electrically connected to the first touch electrode TE1 through a contact hole CNT which penetrates the first touch insulating layer 160 and exposes a portion of the first touch electrode TE1. The first touch electrode TE1 and the second touch electrode TE2 may perform a role of sensing an external touch and transmitting the external touch to a touch driver. For example, the second touch electrode TE2 may include a conductive material. In an embodiment, the first touch electrode TE1 and the second touch electrode TE2 may have a mesh structure in a plan view.

In an embodiment, the reflective pattern RP may be disposed on the first touch insulating layer 160. For example, the reflective pattern RP may be disposed in a trench TRC defined in the first touch insulating layer 160. In an embodiment, the first reflective pattern RP1 may overlap the first light-emitting area EA1, the second reflective pattern RP2 may overlap the second light-emitting area EA2, and the third reflective pattern RP3 may overlap the third light-emitting area EA3 in a plan view. Each of the first, second, and third reflective patterns RP1, RP2, and RP3 may reflect light emitted from the first, second, and third light-emitting elements LED1, LED2, and LED3 to the exterior of the display device 100. For example, a portion of the light emitted from the light-emitting element LED may be reflected by the reflective pattern RP, and a portion of the light reflected by the reflective pattern RP may be reflected again by structure (e.g., the common electrode CE, or the like) under the reflective pattern RP and emitted to the exterior of the display device 100. Accordingly, recycling efficiency of the light emitted from the light-emitting element LED may be improved, so that display quality of the display device 100 may be improved.

In an embodiment, the reflective pattern RP and the second touch electrode TE2 may include a same material. For example, the reflective pattern RP and the second touch electrode TE2 may be formed by the same process or from a same layer. However, the disclosure are not necessarily limited thereto.

The second touch insulating layer 170 may be disposed on the second touch electrode TE2, the reflective pattern RP, and the first touch insulating layer 160. The second touch insulating layer 170 may cover the second touch electrode TE2 and the reflective pattern RP. For example, the second touch insulating layer 170 may include an organic insulating material or an inorganic insulating material. The second touch insulating layer 170 may have a single-layer structure or a multi-layer structure including multiple insulating layers. The second touch insulating layer 170 may planarize an upper surface of the first touch insulating layer 160.

The black matrix BM may be disposed on the second touch insulating layer 170. For example, the black matrix BM may overlap the non-light-emitting area NEA. In an embodiment, the black matrix BM may overlap the pixel defining layer 140, the first touch electrode TE1, and the second touch electrode TE2 in a plan view. For example, the black matrix BM may have a grid shape in a plan view.

The black matrix BM may absorb external light. Accordingly, the black matrix BM may reduce external light reflectance of the display device 100. The black matrix BM may include an organic insulating material and a light-blocking material. Examples of light-blocking materials which can be used as a black matrix BM may include chromium (Cr), chromium oxide (CrOₓ), chromium nitride (CrNₓ), carbon black, a black pigment mixture, a black dye mixture, and/or the like. These can be used alone or in combination with each other. In an embodiment, the black matrix BM and the pixel defining layer 140 may include a same material.

In an embodiment, an opening OP exposing a portion of the second touch insulating layer 170 may be defined in the black matrix BM. For example, a first opening OP1 corresponding to the first light-emitting area EA1, a second opening OP2 corresponding to the second light-emitting area EA2, and a third opening OP3 corresponding to the third light-emitting area EA3 may be defined in the black matrix BM. For example, the first opening OP1 may overlap the first light-emitting area EA1 in a plan view, the second opening OP2 may overlap the second light-emitting area EA2 in a plan view, and the third opening OP3 may overlap the third light-emitting area EA3 in a plan view.

In an embodiment, the light-absorbing pattern LAP may be disposed on the second touch insulating layer 170. For example, the first, second, and third light-absorbing patterns LAP1, LAP2, and LAP3 may be disposed in the first, second, and third light-emitting areas EA1, EA2, and EA3, respectively. In an embodiment, the light-absorbing pattern LAP may be disposed in the opening OP defined in the black matrix BM. For example, the first, second, and third light-absorbing patterns LAP1, LAP2, and LAP3 may be disposed in the first, second, and third openings OP1, OP2, and OP3 defined in the black matrix BM, respectively. In an embodiment, the light-absorbing pattern LAP and the black matrix BM may include a same material. For example, the light-absorbing pattern LAP and the black matrix may be formed by the same process or from the same layer.

The light-absorbing pattern LAP may absorb external light. Accordingly, external light reflectance of the display device 100 may be reduced, reflection color may be improved, and thus display quality of the display device 100 may be improved.

In an embodiment, a shape of the first, second, and third light-absorbing patterns LAP1, LAP2, and LAP3 may be circular in a plan view. However, the disclosure is not necessarily limited thereto. For example, the shape of the first, second, and third light-absorbing patterns LAP1, LAP2, and LAP3 may be an ellipse, a square, a polygon, a rhombus, a track shape, or the like in a plan view.

The color filter layer CF may be disposed on the second touch insulating layer 170, the black matrix BM, and the light-absorbing pattern LAP. For example, the first, second, and third color filters CF1, CF2, and CF3 may be disposed on the first, second, and third light-emitting areas EA1, EA2, and EA3, respectively. The first color filter CF1 may overlap the first light-emitting area EA1 in a plan view, the second color filter CF2 may overlap the second light-emitting area EA2 in a plan view, and the third color filter CF3 may overlap the third light-emitting area EA3 in a plan view. The display device 100 might not include a separate polarizing plate by including the black matrix BM and a color filter layer CF. Accordingly, weight and thickness of the display device 100 may be reduced. In addition, visibility of the display device 100 may be improved.

The color filter layer CF may partially overlap the black matrix BM. Colors of light emitted from the first, second, and third light-emitting elements LED1, LED2, and LED3 may be distinctly perceived by passing through the color filter layer CF.

For example, the first, second, and third color filters CF1, CF2, and CF3 may be spaced apart from each other. However, the disclosure is not necessarily limited thereto. Optionally, the first, second, and third color filters CF1, CF2, and CF3 may partially overlap each other on the black matrix BM.

Each of the first, second, and third color filters CF1, CF2, and CF3 may transmit light of a specific color and may block light of a color other than the specific color. For example, each of the first, second, and third color filters CF1, CF2, and CF3 may include a dye and/or pigment which absorbs (or, blocks) light of a color other than a specific color.

The first color filter CF1 may be disposed in a first opening OP1, the second color filter CF2 may be disposed in a second opening OP2, and the third color filter CF3 may be disposed in a third opening OP3. Accordingly, light emitted from the first light-emitting element LED1 and passing through the first color filter CF1 may be emitted from the first light-emitting area EA1, light emitted from the second light-emitting element LED2 and passing through the second color filter CF2 may be emitted from the second light-emitting area EA2, and light emitted from the third light-emitting element LED3 and passing through the third color filter CF3 may be emitted from the third light-emitting area EA3.

In an embodiment, the first color filter CF1 may cover (or ‘overlap’) the first light-absorbing pattern LAP1 disposed in the first opening OP1, the second color filter CF2 may cover the second light-absorbing pattern LAP2 disposed in the second opening OP2, and the third color filter CF3 may cover the third light-absorbing pattern LAP3 disposed in the third opening OP3.

A color of light selectively transmitted by each of the first, second, and third color filters CF1, CF2, and CF3 may correspond to a color of light emitted by the first, second, and third light-emitting elements LED1, LED2, and LED3, respectively. In an embodiment, the first light-emitting element LED1 emits red light, the second light-emitting element LED2 emits green light, and the third light-emitting element LED3 emits blue light. In this case, the first color filter CF1 may be a red color filter which selectively transmits red light, the second color filter CF2 may be a green color filter which selectively transmits green light, and the third color filter CF3 may be a blue color filter which selectively transmits blue light. However, the disclosure is not necessarily limited thereto.

The first color filter CF1 may include a dye and/or pigment which absorbs (or ‘blocks’) light of a color other than red, the second color filter CF2 may include a dye and/or pigment which absorbs (or ‘blocks’) light of a color other than green, and the third color filter CF3 may include a dye and/or pigment which absorbs (or ‘blocks’) light of a color other than blue.

In an embodiment, the first, second, and third lens structures LEN1, LEN2, and LEN3 may be disposed on the first, second, and third color filters CF1, CF2, and CF3, respectively. For example, the first, second, and third lens structures LEN1, LEN2, and LEN3 may be disposed on the first, second, and third light-emitting areas EA1, EA2, and EA3, respectively.

The first, second, and third lens structures LEN1, LEN2, and LEN3 may refract external light to the first, second, and third light-absorbing patterns LAP1, LAP2, and LAP3, so that the first, second, and third light-absorbing patterns LAP1, LAP2, and LAP3 may absorb the external light. Since a portion of the light emitted from the first, second, and third light-emitting elements LED1, LED2, and LED3 is reflected by the reflective pattern RP and reflected again by underlying structures (e.g., the common electrode CE, or the like) prior to being emitted to the exterior of the display device 100, the light efficiency of the display device 100 may be maintained at a constant level without being affected by the lens structure LEN. Accordingly, the external light reflectance from the display device 100 may be reduced and the light efficiency may be maintained. As a result, the color of the display device 100 and the display quality may be improved.

In an embodiment, the first, second, and third lens structure LEN1, LEN2, and LEN3 may be spaced apart from each other.

In an embodiment, the first, second, and third lens structure LEN1, LEN2, and LEN3 may have a convex shape in a cross-section.

In an embodiment, the lens structure LEN may have a dual structure. For example, the lens structure LEN may include a first lens disposed on the color filter layer CF and overlapping the reflective pattern RP and the light-absorbing pattern LAP, and a second lens entirely surrounding the first lens and having a refractive index greater than a refractive index of the first lens.

In an embodiment, a shape of the first, second, and third lens structures LEN1, LEN2, and LEN3 may be circular in a plan view. However, the disclosure is not necessarily limited thereto. For example, the shape of the first, second, and third lens structures LEN1, LEN2, and LEN3 may be an ellipse, a square, a polygon, a rhombus, a track shape, or the like in a plan view.

The overcoat layer 180 may be disposed on the color filter CF. The overcoat layer 180 may sufficiently cover the black matrix BM, the color filter layer CF, and the lens structure LEN. The overcoat layer 180 may compensate for the step difference of a lower surface, so that it may have a substantially flat upper surface. The overcoat layer 180 may include an organic material. Examples of organic materials which can be used as the overcoat layer 180 may include photoresist, polyacrylic resin, polyimide resin, acrylic resin, epoxy resin, acrylate resin, and/or the like. These can be used alone or in combination with each other.

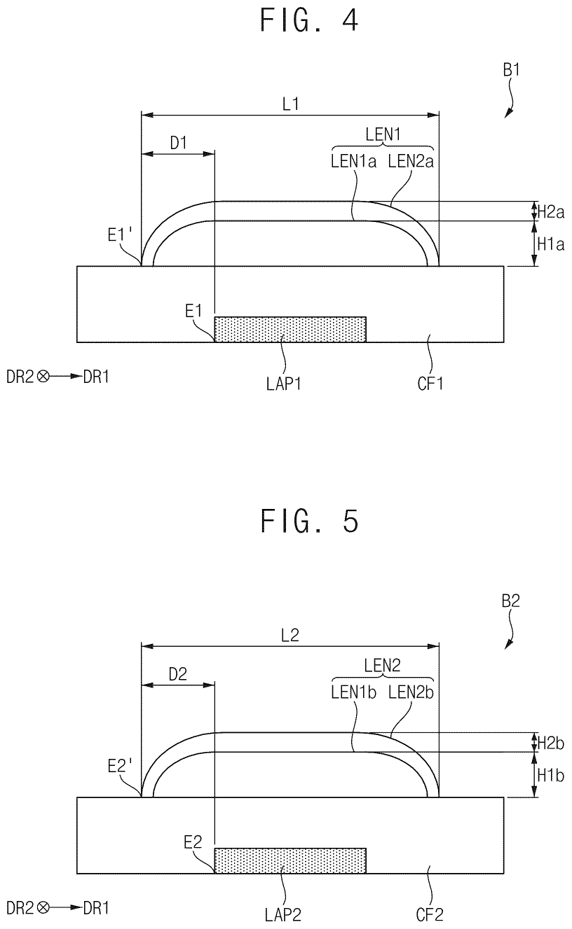

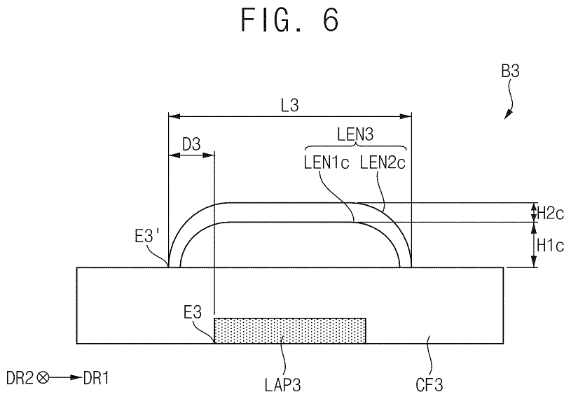

FIG. 4 is an enlarged schematic cross-sectional view of area B1 of FIG. 3. FIG. 5 is an enlarged schematic cross-sectional view of area B2 of FIG. 3. FIG. 6 is an enlarged schematic cross-sectional view of area B3 of FIG. 3. For example, FIG. 4 may illustrate the first light-absorbing pattern LAP1, the first color filter CF1, and the first lens structure LEN1 of FIG. 3, FIG. 5 may illustrate the second light-absorbing pattern LAP2, the second color filter CF2, and the second lens structure LEN2 of FIG. 3, and FIG. 6 may illustrate the third light-absorbing pattern LAP3, the third color filter CF3, and the third lens structure LEN3 of FIG. 3.

Referring to FIGS. 4 to 6, in an embodiment, the first lens structure LEN1 may include a 1-1 lens LEN1a and a 2-1 lens LEN2a, the second lens structure LEN2 may include a 1-2 lens LEN1b and a 2-2 lens LEN2b, and the third lens structure LEN3 may include a 1-3 lens LEN1c and a 2-3 lens LEN2c.

In an embodiment, each of the 2-1 lens LEN2a, the 2-2 lens LEN2b, and the 2-3lens LEN2c may entirely surround the 1-1 lens LEN1a, the 1-2 lens LEN1b, and the 1-3 lens LEN1c.

In an embodiment, the 2-1 lens LEN2a may have a greater refractive index than the 1-1 lens LEN1a, the 2-2 lens LEN2b may have a greater refractive index than the 1-2 lens LEN1b, and the 2-3 lens LEN2c may have a greater refractive index than the 1-3 lens LEN1c. For example, the refractive index of each of the 1-1 lens LEN1a, the 1-2 lens LEN1b, and the 1-3 lens LEN1c may be about 1.6 or more and less than about 1.7, and the refractive index of each of the 2-1 lens LEN2a, the 2-2 lens LEN2b, and the 2-3 lens LEN2c may be about 1.7 or more and less than about 2.5. In case that the refractive index of each of the 1-1, 1-2, and 1-3 lenses LEN1a, LEN1b, and LEN1c satisfies the above-described range and the refractive index of each of the 2-1, 2-2, and 2-3 lenses LEN2a, LEN2b, and LEN2c satisfies the above-described range, external light may be further concentrated in the light-absorbing pattern LAP by the lens structure LEN, and thus the reflectance of the external light may be further reduced.

In an embodiment, the first lens structure LEN1, the second lens structure LEN2, and the third lens structure LEN3 may have different lengths in a direction (e.g., the first direction DR1) parallel to the surface of the substrate 110 (see FIG. 3). The first lens structure LEN1 may have a first length L1 in the first direction DR1, the second lens structure LEN2 may have a second length L2 in the first direction DR1, and the third lens structure LEN3 may have a third length L3 in the first direction DR1.

In an embodiment, the first length L1 of the first lens structure LEN1 and the second length L2 of the second lens structure LEN2 may be substantially the same, and the third length L3 of the third lens structure LEN3 may be shorter than the first length L1 and the second length L2.

Accordingly, in case that the first light-emitting element LED1 emits red light, the second light-emitting element LED2 emits green light, and the third light-emitting element LED3 emits blue light, by forming the third length L3 of the third lens structure LEN3 corresponding to the blue light shorter than each of the first length L1 and the second length L2, it is possible to compensate for distortion or reduction in brightness of the blue light at the side of the display device 100.

In an embodiment, in a plan view, each of a first shortest distance D1 from an edge E1 of the first light-absorbing pattern LAP1 to an edge E1′ of the first lens structure LEN1 and a second shortest distance D2 from an edge E2 of the second light-absorbing pattern LAP2 to an edge E2′ of the second lens structure LEN2 may be longer than a third shortest distance D3 from an edge E3 of the third light-absorbing pattern LAP3 to an edge E3′ of the third lens structure LEN3.

In an embodiment, each of the first shortest distance D1 and the second shortest distance D2 may be about twice the third shortest distance D3.

In an embodiment, the third shortest distance D3 may be about 1 um to about 2 um.

Accordingly, in case that the first light-emitting element LED1 emits red light, the second light-emitting element LED2 emits green light, and the third light-emitting element LED3 emits blue light, by forming the third shortest distance D3 of the third lens structure LEN3 corresponding to the blue light shorter than each of the first shortest distance D1 and the second shortest distance D2, it is possible to compensate for distortion or reduction in brightness of the blue light at the side of the display device 100.

In an embodiment, a thickness H1a of the center of the 1-1 lens LEN1a may be thicker than a thickness H2a of the center of the 2-1 lens LEN2a, a thickness H1b of the center of the 1-2 lens LEN1b may be thicker than a thickness H2b of the center of the 2-2 lens LEN2b, and a thickness H1c of the center of the 1-3 lens LEN1c may be thicker than a thickness H2c of the center of the 2-3 lens LEN2c.

In an embodiment, each of the thicknesses H1a, H1b, and H1c of the centers of the 1-1, 1-2, and 1-3 lenses LEN1a, LEN1b, and LEN1c may be about 1.8 um to about 2.0 um.

In an embodiment, each of the thicknesses H2a, H2b, and H2c of the centers of the 2-1, 2-2, and 2-3 lenses LEN2a, LEN2b, and LEN2c may be about 0.9 um to about 1.0 um.

In case that the thickness of each of the 1-1, 1-2, and 1-3 lenses LEN1a, LEN1b, LEN1c satisfies the above-described range and the thickness of each of the 2-1, 2-2, and 2-3 lenses LEN2a, LEN2b, and LEN2c satisfies the above-described range, external light may be further concentrated in the light-absorbing pattern LAP by the lens structure LEN, and thus the reflectance of the external light may be further reduced.

In an embodiment, each of the first, second, and third lens structures LEN1, LEN2, and LEN3 may have a cross-sectional shape of a trapezoid with rounded sides. However, the disclosure is not necessarily limited thereto.

Accordingly, by including the light absorbing pattern LAP, the reflective pattern RP, and the two-layered lens structure LENS having differing refractive indices that overlaps each light emitting element LED in a plan view, reflection of external light is better suppressed while light extraction efficiency is maintained or improved. Also, by reducing the relative size of the LENS structure as compared to the red sub-pixel and green sub-pixel for the blue sub-pixels, distortion of blue light can be compensated for and luminance of blue light can be reduced.

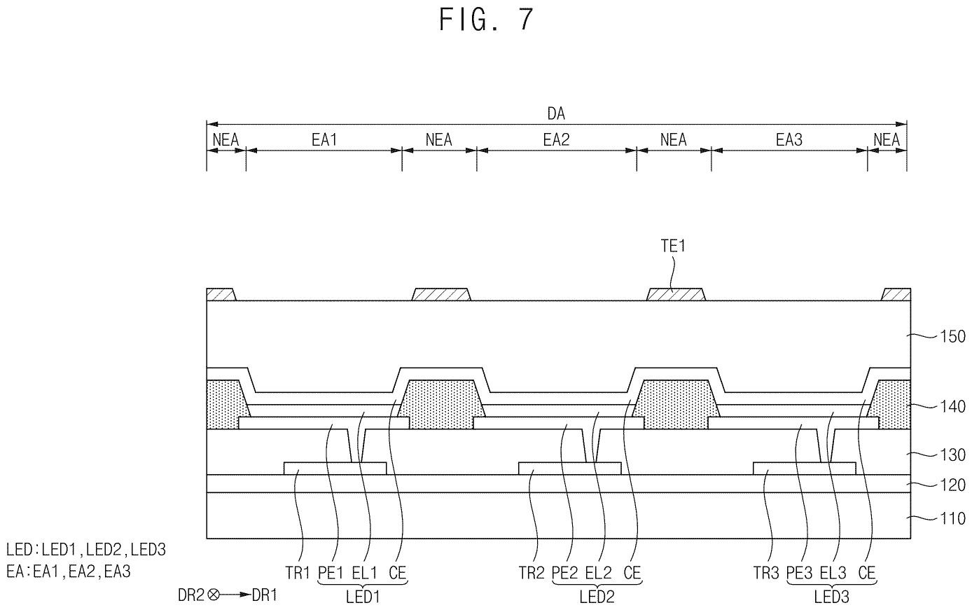

FIGS. 7 to 15 are schematic cross-sectional views illustrating a method for manufacturing a display device according to an embodiment.

Referring to FIG. 7, the buffer layer 120 may be formed on the substrate 110. The first, second, and third transistors TR1, TR2, and TR3 may be formed on the buffer layer 120. The insulating structure 130 may be formed on the first, second, and third transistors TR1, TR2, and TR3. The insulating structure 130 may cover the first, second, and third transistors TR1, TR2, and TR3.

The first, second, and third pixel electrodes PE1, PE2, and PE3 may be formed on the insulating structure 130. The first, second, and third electrodes PE1, PE2, and PE3 may be connected to the first, second, and third transistors TR1, TR2, and TR3 through contact holes penetrating the insulating structure 130, respectively. For example, the first, second, and third pixel electrodes PE1, PE2, and PE3 may be formed using a conductive material.

The pixel defining layer 140 may be formed on the insulating structure 130. The pixel defining layer 140 may cover edges of the first, second, and third pixel electrodes PE1, PE2, and PE3. The pixel opening exposing at least a portion of each of the first, second, and third pixel electrodes PE1, PE2, and PE3 may be formed in the pixel defining layer 140.

The first, second, and third light-emitting layers EL1, EL2, and EL3 may be formed on the portions of the first, second, and third pixel electrodes PE1, PE2, and PE3 exposed by the pixel opening of the pixel defining layer 140, respectively. The common electrode CE may be formed on the first, second, and third light-emitting layers EL1, EL2, and EL3 and the pixel defining layer 140.

Accordingly, the first light-emitting element LED1 including the first pixel electrode PE1, the first light-emitting layer EL1, and the common electrode CE may be formed, a second light-emitting element LED2 including the second pixel electrode PE2, the second light-emitting layer EL2, and the common electrode CE may be formed, and the third light-emitting element LED3 including the third pixel electrode PE3, the third light-emitting layer EL3, and the common electrode CE may be formed.

The encapsulation layer 150 may be formed on the common electrode CE. The encapsulation layer 150 may include the first inorganic encapsulation layer disposed on the common electrode CE, the organic encapsulation layer disposed on the first inorganic encapsulation layer, and the second inorganic encapsulation layer disposed on the organic encapsulation layer.

The first touch electrode TE1 may be formed on the encapsulation layer 150. The first touch electrode TE1 may be formed in the non-light-emitting area NEA. For example, the first touch electrode TE1 may be formed using a conductive material.

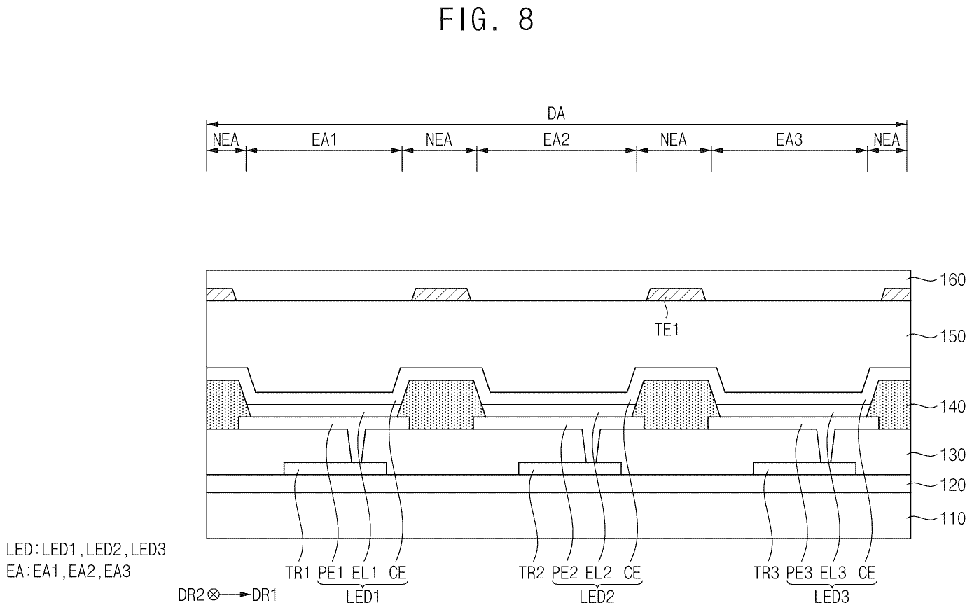

Referring to FIG. 8, the first touch insulating layer 160 may be formed on the first touch electrode TE1 and the encapsulation layer 150. For example, the first touch insulating layer 160 may be formed using an inorganic insulating material or an organic insulating material.

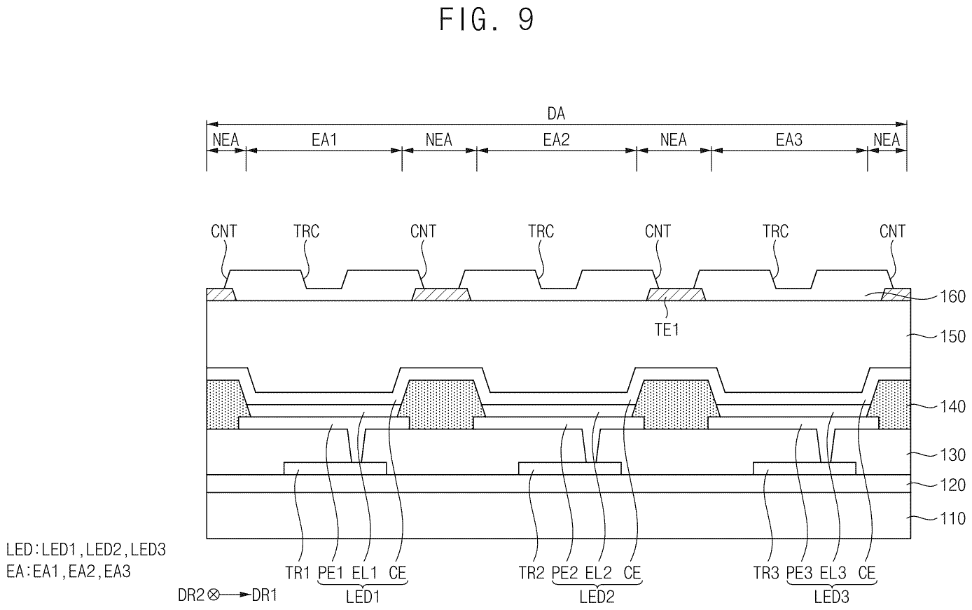

Referring to FIG. 9, the contact hole CNT and the trench TRC may be formed in the first touch insulating layer 160 by removing a portion of the first touch insulating layer 160. In an embodiment, the contact hole CNT may be formed in the non-light-emitting area NEA, and the trench TRC may be formed in each of the first, second, and third light-emitting areas EA1, EA2, and EA3. The contact hole CNT may expose a portion of the first touch electrode TE1. In an embodiment, the contact hole CNT and the trench TRC may be formed simultaneously through the same process.

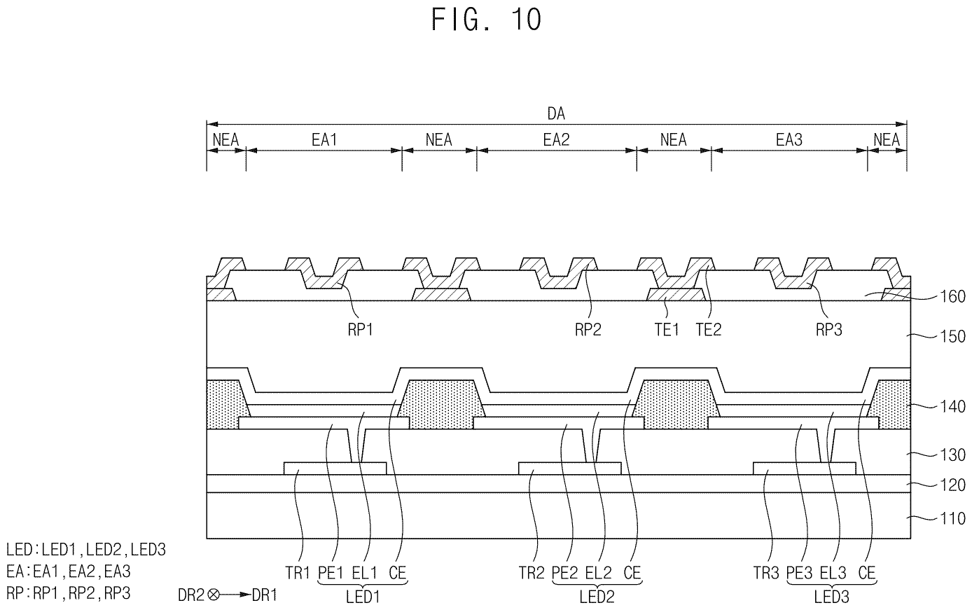

Referring to FIG. 10, the second touch electrode TE2 and the reflective pattern RP may be formed on the first touch insulating layer 160. The second touch electrode TE2 may be electrically connected to the first touch electrode TE1 through the contact hole CNT. The reflective pattern RP may be formed in the trench TRC. In an embodiment, the reflective pattern RP and the second touch electrode TE2 may be formed simultaneously by the same process and/or from a same layer.

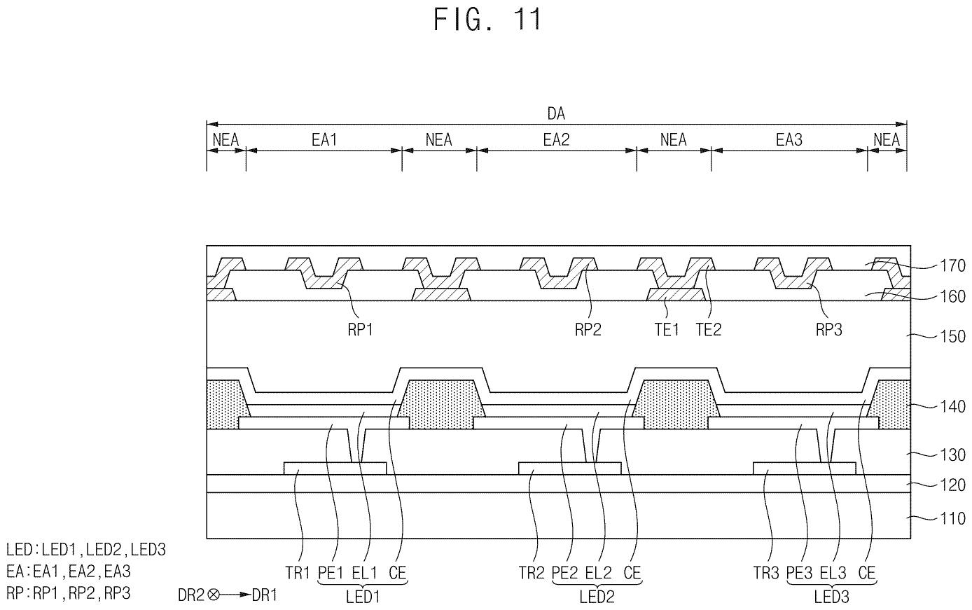

Referring to FIG. 11, the second touch insulating layer 170 may be formed on the second touch electrode TE2, the reflective pattern RP and the first touch insulating layer 160. For example, the second touch insulating layer 170 may be formed using an inorganic insulation material or an organic insulation material.

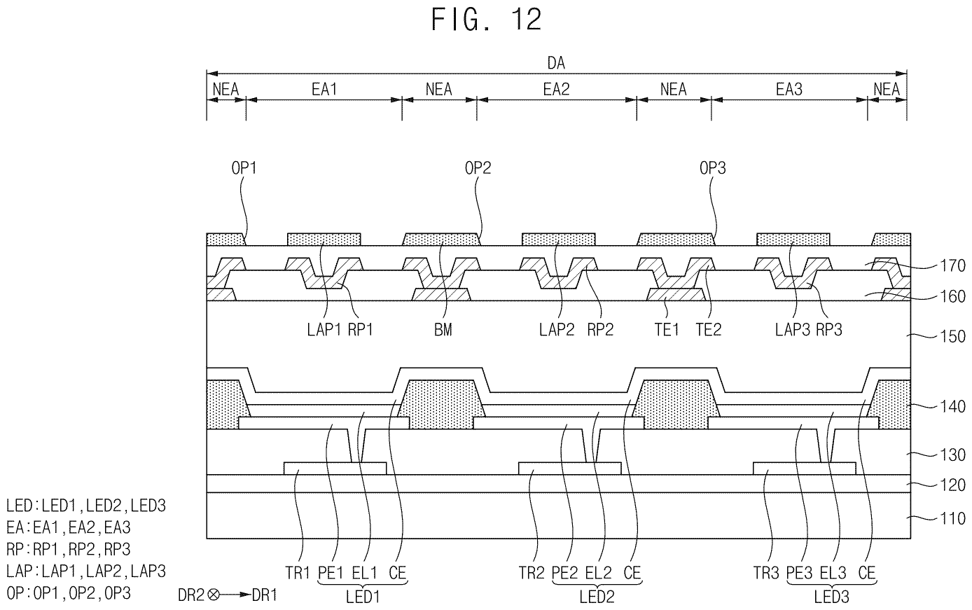

Referring to FIG. 12, the black matrix BM and the light-absorbing pattern LAP may be formed on the second touch insulating layer 170. The black matrix BM may be formed in the non-light-emitting area NEA. The first opening OP1 corresponding to the first light-emitting area EA1, the second opening OP2 corresponding to the second light-emitting area EA2, and the third opening OP3 corresponding to the third light-emitting area EA3 may be defined in the black matrix BM.

In an embodiment, the first, second, and third light-absorbing patterns LAP1, LAP2, and LAP3 may be formed in the first, second, and third light-emitting areas EA1, EA2, and EA3, respectively. In an embodiment, the first, second, and third light-absorbing patterns LAP1, LAP2, and LAP3 may be formed in the first, second, and third openings OP1, OP2, and OP3 defined from the black matrix BM, respectively.

In an embodiment, the black matrix BM may be formed using a light-blocking material having a black color. The first, second, and third light-absorbing patterns LAP1, LAP2, and LAP3 and the black matrix BM may include a same material. For example, the first, second, and third light-absorbing patterns LAP1, LAP2, and LAP3 and the black matrix may be formed simultaneously by the same process and/or from a same layer.

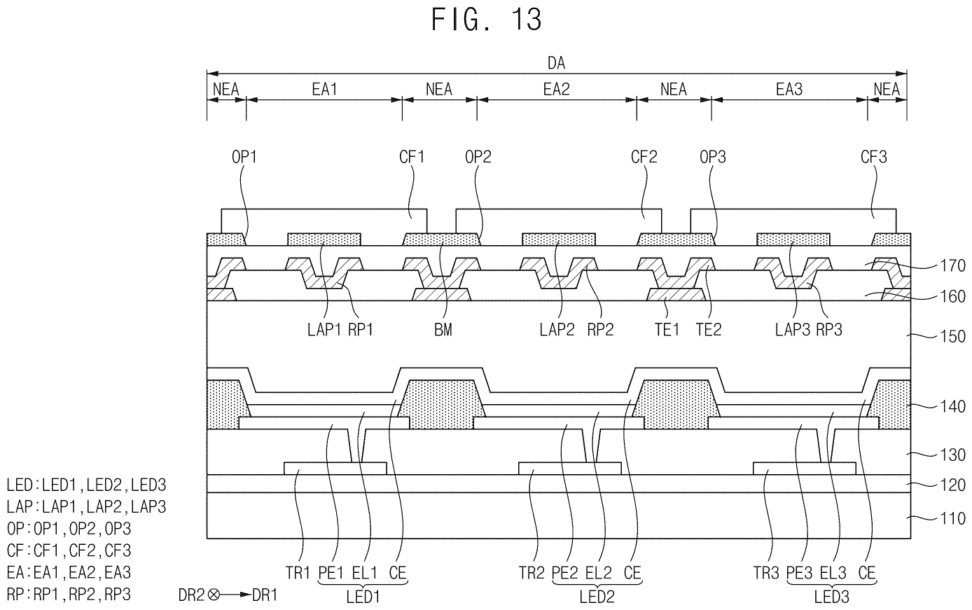

Referring to FIG. 13, the first, second, and third color filters CF1, CF2, and CF3 may be formed in the first, second, and third openings OP1, OP2, and OP3, respectively. The first color filter CF1 may be formed using a dye and/or pigment which absorbs light of a color other than red, the second color filter CF2 may be formed using a dye and/or pigment which absorbs light of a color other than green, and the third color filter CF3 may be formed using a dye and/or pigment which absorbs light of a color other than blue.

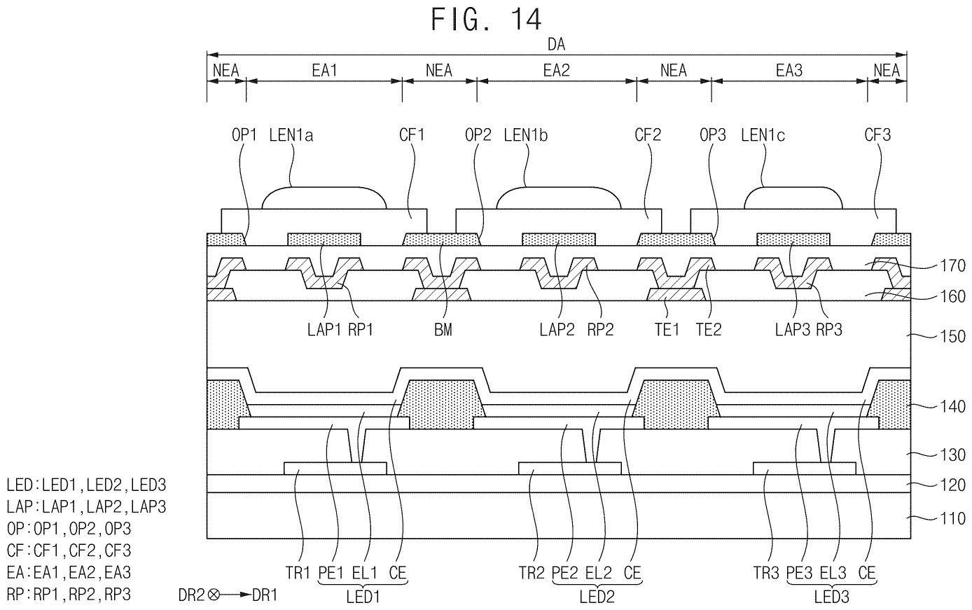

Referring to FIG. 14, the 1-1 lens LEN1a may be formed on the first color filter CF1, the 1-2 lens Len1b may be formed on the second color filter CF2, and the 1-3 lens LEN1c may be formed on the third color filter CF3. For example, the 1-1 lens LEN1a may be formed to overlap the first light-emitting area EA1, the 1-2 lens LEN1b may be formed to overlap the second light-emitting area EA2, and the 1-3 lens LEN1c may be formed to overlap the third light-emitting area EA3.

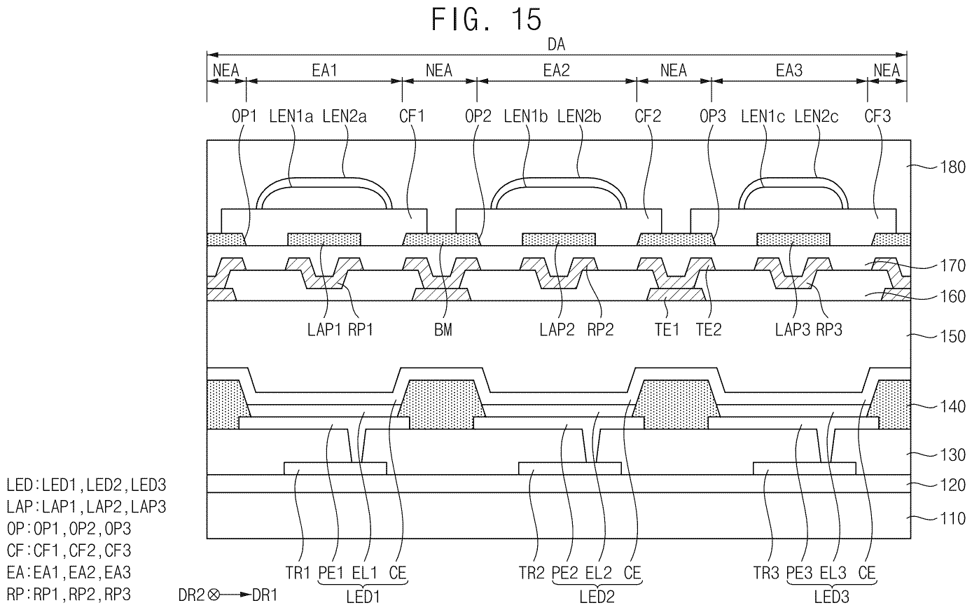

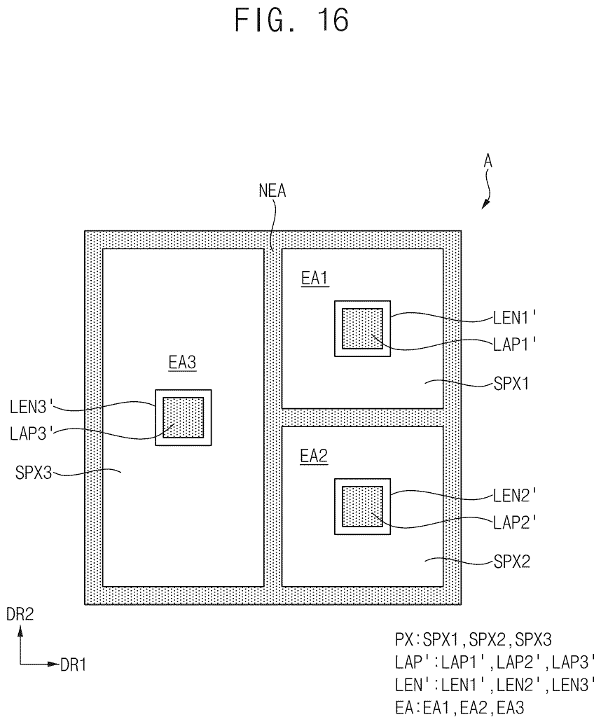

Referring to FIG. 15, the 2-1 lens LEN2a, the 2-2 lens LEN2b, and the 2-3 lens LEN2c may be formed to entirely surround the 1-1 lens LEN1a, the 1-2 lens LEN1b, and the 1-3 lens LEN1c, respectively.

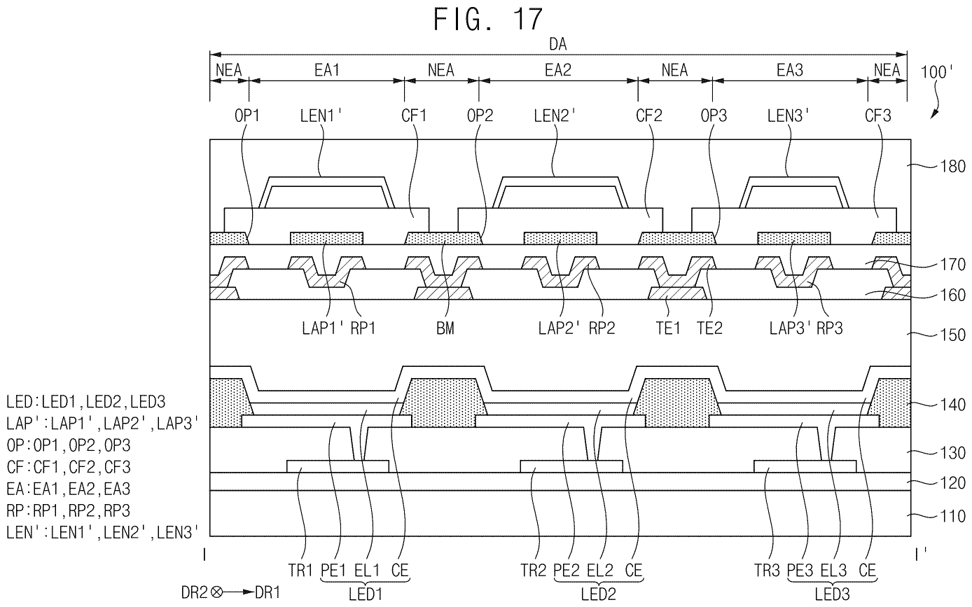

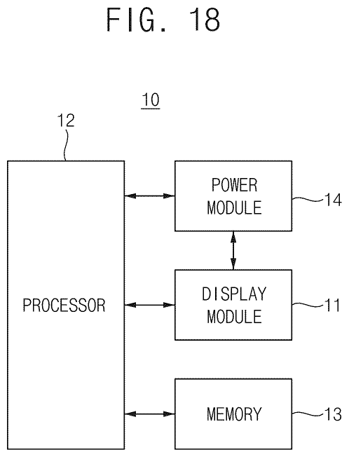

FIG. 16 is a plan view of an embodiment, which is an enlarged view of area A of FIG. 1. FIG. 17 is a schematic cross-sectional view of an embodiment taken along line I-I′ of FIG. 2. In the following description, the differences from the display device 100 described with reference to FIGS. 2 and 3 will be explained, and any redundant description will be omitted or simplified.

Referring to FIG. 16, in an embodiment, the shape of the first, second, and third light-absorbing patterns LAP1′, LAP2′, and LAP3′ may be a quadrangle (e.g., a rectangle or a square) in a plan view. However, the disclosure is not necessarily limited thereto. For example, the shape of the first, second, and third light-absorbing patterns LAP1′, LAP2′, and LAP3′ may be an ellipse, a polygon, a rhombus, a track shape, or the like in a plan view.

In an embodiment, the shape of the first, second, and third lens structures LEN1′, LEN2′, and LEN3′ may be a quadrangle (e.g., a rectangle or a square) in a plan view. However, the disclosure is not necessarily limited thereto. For example, the shape of the first, second, and third lens structures LEN1′, LEN2′, and LEN3′ may be an ellipse, a polygon, a rhombus, a track shape, or the like in a plan view.

Referring to FIG. 17, each or the first, second, and third lens structures LEN1′, LEN2′, and LEN3′ may have a trapezoidal cross-sectional shape. However, the disclosure is not necessarily limited thereto.

The display device 100′ according to embodiments of the disclosure may be applied to various electronic devices. An electronic device according to an embodiment includes the display device 100′ described above, and may further include a module or device having additional functions in addition to the display device 100′.

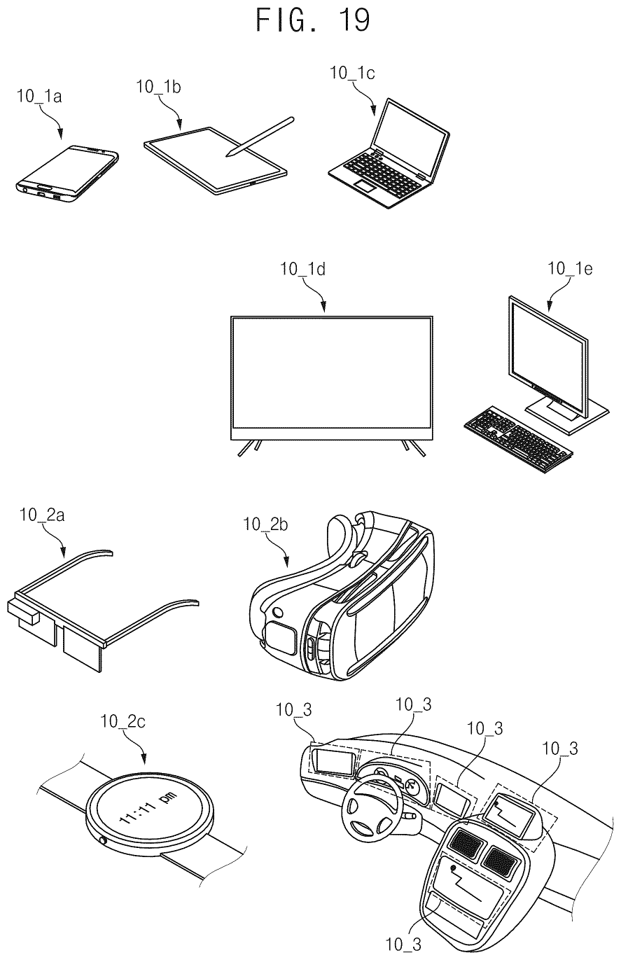

FIG. 18 is a schematic block diagram of an electronic device according to an embodiment of the disclosure.

Referring to FIG. 18, the electronic device 10 according to an embodiment may include a display module 11, a processor 12, a memory 13, and a power module 14.

The processor 12 may control the display device. The processor 12 may include at least one of a central processing unit (CPU), an application processor (AP), a graphic processing unit (GPU), a communication processor (CP), an image signal processor (ISP), and a controller.

Data information necessary for the operation of the processor 12 or the display module 11 may be stored in the memory 13. In a case where the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module which converts power supplied by the power supply module to generate power required for the operation of the electronic device 10.

At least one of the components of the electronic device 10 described above may be included in a display device (e.g., the display devices 100 and 100′ of FIGS. 1 and 17, respectively) according to the embodiments described above. Some of the individual modules functionally included in a single module may be included in the display device, while others may be provided separately from the display device. For example, the display device may include the display module 11, and the processor 12, the memory 13, and the power module 14 may be provided in the form of other devices in the electronic device 10 other than the display device.

FIG. 19 is a schematic diagram of various electronic devices according to various embodiments.

Referring to FIG. 19, various electronic devices to which display devices according to embodiments (for example, display devices 100 and 100′ of FIGS. 1 and 17, respectively) are applied may include not only image display electronic devices such as a smart phone 10_1b, a tablet 10_1b, a laptop 10_1c, a TV 10_1d, and a desk monitor 10_1e, but also wearable electronic devices including display module such as smart glasses 10_2a, a head mounted display 10_2b, and a smart watch 10_2c, and vehicle electronic devices 10_3 including display modules such as a center information display (CID) and a room mirror display arranged on an instrument panel, a center fascia, and a dashboard of an automobile.

The disclosure may be applied to a display device and an electronic device including the same. For example, the disclosure may be applied to high-resolution smart phones, mobile phones, smart pads, smart watches, tablets, vehicle navigation systems, televisions, computer monitors, laptops, or the like.

Although the disclosure has been described with reference to embodiments thereof, it will be understood by those skilled in the art which various modifications and changes may be made therein without departing from the spirit and scope of the disclosure as set forth in the claims below.

What is claimed is:

1. A display device comprising:
a substrate including light-emitting areas and a non-light-emitting area surrounding the light-emitting areas;
light-emitting elements disposed in the light-emitting areas on the substrate, respectively;
a reflective pattern disposed on the light-emitting elements which reflects light emitted from the light-emitting elements to an exterior space;
a light-absorbing pattern disposed on the reflective pattern which absorbs external light;
a color filter layer disposed on the light-absorbing pattern and overlapping the light-absorbing pattern in a plan view; and
a lens structure disposed on the color filter layer and which redirects a path of the external light to the light-absorbing pattern.

2. The display device of claim 1, wherein the lens structure includes:
a first lens disposed on the color filter layer and overlapping the reflective pattern and the light-absorbing pattern in a plan view; and
a second lens entirely surrounding the first lens and having a refractive index greater than a refractive index of the first lens.

3. The display device of claim 2, wherein
the refractive index of the first lens is in a range of about 1.6 to about 1.7, and
the refractive index of the second lens is in a range of about 1.7 to about 2.5.

4. The display device of claim 2, wherein
a thickness of a center of the first lens is in a range of about 1.8 um to about 2.0 um, and
a thickness of a center of the second lens is in a range of about 0.9 um to about 1.0 um.

5. The display device of claim 2, wherein each of the light-absorbing pattern and the lens structure has a circular shape or a rectangular shape in a plan view.

6. The display device of claim 2, wherein
the light-emitting areas include first, second and third light-emitting areas which emit light of different colors,
the color filter layer includes first, second and third color filters overlapping the first, second and third light-emitting areas, respectively in a plan view,
the lens structure includes first, second and third lens structures overlapping the first, second and third light-emitting areas, respectively in a plan view,
the first lens structure has a first length in a direction parallel to a surface of the substrate,
the second lens structure has a second length in the direction, and
the third lens structure has a third length in the direction which is shorter than each of the first length and the second length.

7. The display device of claim 6, wherein
the light-absorbing pattern includes first, second and third light-absorbing patterns overlapping the first, second and third light-emitting areas, respectively in a plan view, and
a first shortest distance from an edge portion of the first light-absorbing pattern to an edge portion of the first lens structure or a second shortest distance from an edge portion of the second light-absorbing pattern to an edge portion of the second lens structure is about twice a third shortest distance from an edge portion of the third light-absorbing pattern to an edge portion of the third lens structure in a plan view.

8. The display device of claim 7, wherein the third shortest distance is in a range of about um to about 2 um.

9. The display device of claim 6, wherein the first color filter is a red color filter,
the second color filter is a green color filter, and
the third color filter is a blue color filter.

10. The display device of claim 1, further comprising:
a black matrix disposed in the non-light-emitting area and on the reflective pattern,
wherein the light-absorbing pattern and the black matrix include a same material.

11. The display device of claim 1, further comprising:
a first touch electrode disposed in the non-light-emitting area;
a second touch electrode disposed on the first touch electrode and connected to the first touch electrode; and
an overcoat layer overlapping the color filter layer and the lens structure.

12. The display device of claim 11, wherein the reflective pattern and the second touch electrode include a same material.

13. The display device of claim 1, wherein the lens structure has a cross-sectional shape which is a trapezoid or a trapezoid with rounded sides.

14. The display device of claim 1, wherein the lens structure has a convex shape in a cross section.

15. An electronic device comprising:
a display device including:
a substrate including light-emitting areas and a non-light-emitting area surrounding the light-emitting areas;
light-emitting elements disposed in the light-emitting areas on the substrate, respectively;
a reflective pattern disposed on the light-emitting elements which reflects light emitted from the light-emitting elements to an exterior space;
a light-absorbing pattern disposed on the reflective pattern which absorbs external light;
a color filter layer disposed on the light-absorbing pattern and overlapping the light-absorbing pattern in a plan view; and
a lens structure disposed on the color filter layer and which redirects path of the external light to the light-absorbing pattern, and
a processor which controls the display device.

16. The electronic device of claim 15, wherein the lens structure includes:
a first lens disposed on the color filter layer and overlapping the reflective pattern and the light-absorbing pattern in a plan view; and
a second lens entirely surrounding the first lens and having a refractive index greater than a refractive index of the first lens.

17. The electronic device of claim 16, wherein
the refractive index of the first lens is in a range of about 1.6 to about 1.7, and
the refractive index of the second lens is in a range of about 1.7 to about 2.5.

18. The electronic device of claim 16, wherein
a thickness of a center of the first lens is in a range of about 1.8 um to about 2.0 um, and
a thickness of a center of the second lens is in a range of about 0.9 um to about 1.0 um.

19. The electronic device of claim 15, wherein
the light-emitting areas include first, second and third light-emitting areas which emit light of different colors,
the color filter layer includes first, second and third color filters overlapping the first, second and third light-emitting areas, respectively in a plan view,
the lens structure includes first, second and third lens structures overlapping the first, second and third light-emitting areas, respectively in a plan view,
the first lens structure has a first length in a direction parallel to a surface of the substrate,
the second lens structure has a second length in the direction, and
the third lens structure has a third length in the direction which is shorter than each of the first length and the second length.

20. The electronic device of claim 19, wherein
the light-absorbing pattern includes first, second and third light-absorbing patterns overlapping the first, second and third light-emitting areas, respectively in a plan view,
a first shortest distance from an edge portion of the first light-absorbing pattern to an edge portion of the first lens structure or a second shortest distance from an edge portion of the second light-absorbing pattern to an edge portion of the second lens structure is about twice a third shortest distance from an edge portion of the third light-absorbing pattern to an edge portion of the third lens structure in a plan view, and
the third shortest distance is in a range of about 1 um to about 2 um in a plan view.
